(19) United States
(12) Patent Application Publication
(10) Pub. No.: US 2009/0115067 A1
(43) Pub. Date: May 7, 2009

(54) MODULE HAVING BUILT-IN ELECTRONIC COMPONENT AND METHOD FOR MANUFACTURING SUCH MODULE

(75) Inventors: Rikiya Okimoto, Osaka (JP); Toshiyuki Kojima, Kyoto (JP); Yukihiro Ishimaru, Osaka (JP)

Correspondence Address: HAMRE, SCHUMANN, MUELLER & LARSON P.C., P.O. BOX 2902-0902, MINNEAPOLIS, MN, 55402, US

(73) Assignee: MATSUSHITA ELECTRIC INDUSTRIAL CO., LTD., Kadoma-shi, Osaka (JP)

(21) Appl. No.: 12/093,223

(22) PCT Filed: Nov. 16, 2006
(86) PCT No.: PCT/JP2006/322869

§ 371 Date: May 9, 2008

(30) Foreign Application Priority Data
Dec. 15, 2005 (JP) 2005-362093

(51) Int. Cl. H01L 23/52; H01L 21/44

(52) U.S. Cl. 257/774; 438/672; 257/E23.141; 257/E21.476

(57) ABSTRACT

An electronic component embedded module that can improve reliability of electric connection of inner vias, and a manufacturing method therefor are provided. A first electronic component (11) is embedded in a second electrical insulating layer (13) and connected electrically to a first wiring pattern (14) through first inner vias (16) that penetrate a first electrical insulating layer (12). The first wiring pattern (14) and a second wiring pattern (15) are connected electrically to each other through second inner vias (17) that penetrate the first electrical insulating layer (12) and third inner vias (18) that penetrate the second electrical insulating layer (13). The second inner vias (17) and the third inner vias (18) are arranged continuously.

### TECHNICAL FIELD

The present invention relates to an electronic component embedded module that embeds an electronic component, and a method for manufacturing the same.

### BACKGROUND ART

With the recent trend for smaller and lightweight electronic equipment, demands for high-density printed circuit boards and small surface-mounted components have become stricter. For the printed circuit boards, efforts have been made to increase the density in a direction parallel to the circuit board surface by narrowing the wiring rule. Further, a buildup method is employed to laminate circuit boards, and inner vias are formed perpendicular to the circuit board surfaces.

For the purpose of providing smaller surface-mounted components, a CSP (Chip Size Package) has been used widely. This is prepared by flip-chip mounting an active element side of a semiconductor chip to face a circuit board. In the flip chip mounting, a semiconductor bare chip is mounted directly on a circuit board through a solder bump or an Au stud bump, without using a lead.

For the purpose of realizing a package with higher density, technology of three-dimensional mounting has been developed, by embedding thin film such as a semiconductor device and a passive component (see for example, Patent document 1 and Patent document 2).

Hereinafter, a method for manufacturing a conventional electronic component embedded module will be described with reference to the attached figures. FIGS. 18A-18D are cross-sectional views showing steps of manufacturing a conventional electronic component embedded module. First, as shown in FIG. 18A, a wiring pattern 502 is formed on a peelable carrier 501, on which an electronic component 503 is flip-chip mounted. For mounting, when the electronic component 503 is a semiconductor chip for example, the electronic component 503 and the wiring pattern 502 can be connected electrically to each other through a gold bump 504. And a sealing agent 505 is injected into the space between the wiring pattern 502 and the electronic component 503.

Next, as shown in FIG. 18B, an electrical insulating substrate 507 is prepared. The electrical insulating substrate 507 is formed with through holes, and the through holes are filled with a conductive resin composition 506. The electrical insulating substrate 507 and the peelable carrier 501 are aligned and laminated. At the same time, the electrical insulating substrate 507 and a peelable carrier 509 formed with a wiring pattern 508 are aligned and laminated.

Next, as shown in FIG. 18C, the peelable carrier 501 and the peelable carrier 509 are heated under pressure applied from the outside.

Next, the peelable carrier 501 and the peelable carrier 509 are peeled off to obtain an electronic component embedded module as shown in FIG. 18D

However, in an electronic component embedded module obtained by the above-described manufacturing method, the sealing agent injected into the space between the semiconductor chip and the wiring pattern will spew out from the edge face of the semiconductor ship, resulting in difficulty in arranging inner vias in the vicinity of the semiconductor chip.

Patent document 3 discloses a resolution of this problem as shown in FIG. 19, in which both an electronic component 601 and a surrounding wiring pattern 602 are sealed with a sealing agent 603, and inner vias 604 that penetrate the sealing agent 603 are provided, thereby enabling arrangement of the inner vias in the vicinity of the electronic component 601.

Patent document 1: JP H11-220262 A
Patent document 2: JP2002-57276 A
Patent document 3: JP2001-244638A

However, in the electronic component embedded module disclosed by Patent document 3, the space for forming an inner a becomes a blind via. As a result, in the step of filling the space with a conductive resin composition, it is difficult to fill the space fully to the bottom with the conductive resin composition. Moreover, the chips formed during the blind via processing make a residue, and the residue may adhere onto the wiring pattern for inner via connection, which may degrade the reliability of the electric connection of the inner vias.

Furthermore, since the sealing resin should be provided to cover the semiconductor chip, the thickness of the sealing resin layer will be 400 μm or more when considering the semiconductor chip thickness and the bump height for the semiconductor chip mounting. Therefore, the aspect ratio of the inner via to be formed will be at least 1. As a result, filling with the conductive resin composition may be difficult, and there may be a risk that a clearance is formed between the conductive resin composition and a land for connecting inner vias. This may degrade further the reliability of the electric connection of the inner vias. On the other hand, when the inner via diameter is increased to 400 μm or more for the purpose of lowering the aspect ratio, the wiring pattern density is lowered and thus the high-density mounting will be difficult.

In addition to that, the face of the semiconductor chip opposite to the active element face (hereinafter, it may be referred to “back face” simply) has a low adhesion to the sealing resin. And thus, when a crack occurs between the back face and the sealing resin, the crack may spread up to the interface between the sealing resin and the inner vias. Similarly in this case, the reliability of the electric connection of the inner vias may deteriorate.

### DISCLOSURE OF INVENTION

For solving the above-mentioned problems, an object of the present invention is to provide an electronic component embedded module that enables arrangement of inner vias in the vicinity of an electronic component and that can improve the reliability of electric connection of the inner vias, and a method for manufacturing the same.

A first electronic component embedded module of the present invention is an electronic component embedded module including: an electrical insulating substrate and a first electronic component embedded in the electrical insulating substrate, the electrical insulating substrate comprises a first electrical insulating layer and a second electrical insulating layer laminated on the first electrical insulating layer, a first wiring pattern is disposed on a main face of the first electrical insulating layer opposite to the second electrical insulating layer, a second wiring pattern is disposed on a main face of the second electrical insulating layer opposite to the first electrical insulating layer, the first electronic component is embedded in the second electrical insulating layer and connected electrical to the first wiring pattern through first inner vias that penetrate the first electrical insulating layer, the first wiring pattern and the second wiring pattern are connected electrically to each other through second inner vias that penetrate the first electrical insulating layer and third inner vias that penetrate the second electrical insulating layer, and the second inner vias and the third inner vias are arranged continuously.

A second electronic component embedded module of the present invention is an electronic component embedded module including: an electrical insulating substrate, and a first electronic component and a second the electrical insulating substrate comprises a first electrical insulating layer, a second electrical insulating layer, and a third electrical insulating layer that is sandwiched by the first and second electrical insulating layers, a first wiring pattern is disposed on a main face of the first electrical insulating layer opposite to the third electrical insulating layer, a second wiring pattern is disposed on a main face of the second electrical insulating layer opposite to the third electrical insulating layer, the first electronic component is embedded in the third electrical insulating layer and connected electrically to the first wiring pattern through first inner vias that penetrate the first electrical insulating layer, the second electronic component is embedded in the third electrical insulating layer and connected electrically to the second wiring pattern through second inner vias that penetrate the second electrical insulating layer, the first wiring pattern and the second wiring pattern are connected electrically to each other through third inner vias that penetrate the first electrical insulating layer, fourth inner vias that penetrate the third electrical insulating layer, and fifth inner vias that penetrate the second electrical insulating layer, and the third inner vias, the fourth inner vias and the fifth inner vias are arranged continuously.

A first method for manufacturing an electronic component embedded module of the present invention includes steps of: (a) forming first through holes and second through holes in a first electrical insulating layer, and filling the first and second through holes respectively with a first conductive resin composition, (b) laminating the first electrical insulating layer on a first base with a first wiring pattern formed thereon so that the first wiring pattern and the first conductive resin composition are in contact with each other, and disposing an electronic component on the first through holes filled with the first conductive resin composition, thereby forming a first laminate, (c) forming third through holes in a second electrical insulating layer and filling the third through holes with a second conductive resin composition, (d) laminating the second electrical insulating layer on the first laminate so as to position the third through holes filled with the second conductive resin composition on the second through holes filled with the first conductive resin composition, and laminating a second base with a second wiring pattern formed thereon on the second electrical insulating layer so that the second wiring pattern and the second conductive resin composition are in contact with each other, thereby forming a second laminate, and (e) subjecting the second laminate to heat and pressure so that the electronic component is embedded in the second electrical insulating layer, the electronic component and the first wiring pattern are connected electrically to each other through first inner vias made of the first conductive resin composition, and the first wiring pattern and the second wiring pattern are connected electrically to each other through second inner vias made of the first conductive resin composition and third inner vias made of the second conductive resin composition.

A second method for manufacturing an electronic component embedded module of the present invention includes steps of: (I) forming first through holes and second through holes in a first electrical insulating layer, and filling the first and second through holes respectively with a first conductive resin composition, (II) laminating the first electrical insulating layer on a first base with a first wiring pattern formed thereon so that the first wiring pattern and the first conductive resin composition are in contact with each other, and disposing a first electronic component on the first through holes filled with the first conductive resin composition, thereby forming a first laminate, (III) forming third through holes and fourth through holes in a second electrical insulating layer, and filling the third and fourth through holes respectively with a second conductive resin composition, (IV) laminating the second electrical insulating layer on a second base with a second wiring pattern formed thereon so that the second wiring pattern and the second conductive resin composition are in contact with each other, and disposing a second electronic component on the third through holes filled with the second conductive resin composition, thereby forming a second laminate, (V) forming fifth through holes in a third electrical insulating layer and filling the fifth through holes with a third conductive resin composition, (VI) sandwiching the third electrical insulating layer with the first and second laminates so that the fifth through holes filled with the third conductive resin composition are positioned between the second through holes filled with the first conductive resin composition and the fourth through holes filled with the second conductive resin composition, thereby forming a third laminate, and (VII) subjecting the third laminate to heat and pressure so that the first an second electronic components are embedded in the third electrical insulating layer; the first electronic component and the first wiring pattern are connected electrically to each other through first inner vias made of the first conductive resin composition; the second electronic component and the second wiring pattern are connected electrically to each other through second inner vias made of the second conductive resin composition; and the first wiring pattern and the second wiring pattern are connected electrically to each other through third inner vias made of the first conductive resin composition, fourth inner vias made of the third conductive resin composition, and fifth inner vias made of the second conductive resin composition.

### BRIEF DESCRIPTION OF DRAWINGS

FIG. 1 is a cross-sectional view showing an electronic component embedded module according to First Embodiment of the present invention.

FIG. 2 is a cross-sectional view showing a variation of an electronic component embedded module according to First Embodiment of the present invention.

FIG. 3 is a cross-sectional view showing a variation of an electronic component embedded module according to First Embodiment of the present invention.

FIG. 4 is a cross-sectional view showing a variation of an electronic component embedded module according to First Embodiment of the present invention.

FIG. 5 is a cross-sectional view showing a variation of an electronic component embedded module according to First Embodiment of the present invention.

FIGS. 6A-6F are cross-sectional views for describing a preferable method for manufacturing an electronic component embedded module according to First Embodiment of the present invention.

FIG. 7 is a cross-sectional view showing an electronic component embedded module according to Second Embodiment of the present invention.

FIG. 8 is a cross-sectional view showing a variation of an electronic component embedded module according to Second Embodiment of the present invention.

FIG. 9 is a cross-sectional view showing a variation of an electronic component embedded module according to Second Embodiment of the present invention.

FIG. 10 is a cross-sectional view showing a variation of an electronic component embedded module according to Second Embodiment of the present invention.

FIG. 11 is a cross-sectional view showing a variation of an electronic component embedded module according to Second Embodiment of the present invention.

FIGS. 12A-12F are cross-sectional views for describing a preferable method for manufacturing an electronic component embedded module according to Second Embodiment of the present invention.

FIGS. 13A and 13B are cross-sectional views showing an electronic component embedded module according to another embodiment of the present invention.

FIGS. 14A and 14B are cross-sectional views showing an electronic component embedded module according to another embodiment of the present invention.

FIG. 15 is a cross-sectional view showing an electronic component embedded module according to another embodiment of the present invention.

FIG. 16 is a cross-sectional view showing an electronic component embedded module according to another embodiment of the present invention.

FIGS. 17A-17F are cross-sectional views for describing a preferable method for manufacturing an electronic component embedded module shown in FIG. 16.

FIGS. 18A-18D are cross-sectional views showing steps of manufacturing a conventional electronic component embedded module.

FIG. 19 is a cross-sectional view showing a conventional electronic component embedded module.

### DESCRIPTION OF THE INVENTION

A first electronic component embedded module of the present invention includes an electrical insulating substrate and a first electronic component embedded in this electrical insulating substrate. The electrical insulating substrate includes a first electrical insulating layer and a second electrical insulating layer laminated on this first electrical insulating layer. A first wiring pattern is disposed on a main face of the first electrical insulating layer opposite to the second electrical insulating layer. A second wiring pattern is disposed on a main face of the second electrical insulating layer opposite to the first electrical insulating layer. Here, the “main face of the first electrical insulating layer opposite to the second electrical insulating layer” denotes a front face of the first electrical insulating layer opposite to the second electrical insulating layer side in a plan view. This principle is applied similarly to the expression “main face of the second electrical insulating layer opposite to the first electrical insulating layer”.

For the first electronic component, for example, an active element and a passive element can be used. For the active element, for example, semiconductor elements such as a transistor, IC (Integrated Circuit) and LSI (Large Scale Circuit) can be used. For the passive element, for example, an inductor, a capacitor, a resistor and the like can be used.

For the first and second electrical insulating layers, for example, an electric insulating material based on a thermosetting resin such as an epoxy resin, a phenol resin and polyimide can be used. Among them, an electric insulating material including a thermosetting resin and an inorganic filler such as SiO₂ is used preferably since the mechanical strength of the first electrical insulating layer can be improved. Particularly, a material that does not deteriorate during a hot process such as a reflow step (for example, a heat-resistant material that can resist heat of 240° C. for at least 10 seconds) is preferred. An example of such materials is a composite material including 10-40 wt % of epoxy resin and 60-90 wt % of SiO₂ filler. Preferably, the material of the first electrical insulating layer and the material of the second electrical insulating layer are identical, since it is effective in preventing warping and cracks caused by the difference in the linear expansion coefficients of the respective layers, thereby providing an electronic component embedded module with a highly reliable electric connection.

The first and second wiring patterns are formed of electrically conductive materials such as a copper foil or a conductive resin composition. When a copper foil is used for the first and second wiring patterns, for example, a copper foil having a thickness of about 12 μm to about 35 μm made by electroplating can be used. It is desirable that a surface of the copper foil in use, which will be in contact with the electrical insulating layer, is roughened to improve the adhesion with the electrical insulating layer. Alternatively, a copper foil whose surface is subjected to a coupling treatment or a copper foil plated with tin, zinc, nickel or the like, can be used. Thereby, the adhesion with the electrical insulating layer and the oxidation resistance can be improved.

In the first electronic component embedded module of the present invention, the first electronic component is embedded in the second electrical insulating layer and connected electrically to the first wiring pattern through the first inner vias that penetrate the first electrical insulating layer. Thereby, there is no necessity of forming a gold bump, a solder bump or the like as a conventional electric connection component, and the process of manufacturing the electronic component embedded module can be simplified.

The first wiring pattern and the second wiring pattern are connected electrically to each other through second inner vias that penetrate the first electrical insulating layer and third inner vias that penetrate the second electrical insulating layer, and the second inner vias and the third inner vias are arranged continuously. Due to this configuration, as described below, it is possible to form through holes in the first and second electrical insulating layers and to fill these through holes with a conductive resin composition before laminating the first electrical insulating layer and the second electrical insulating layer. Namely, since such through holes can be employed as space for providing inner vias, filling of the conductive resin composition can be carried out in a reliable manner, thereby improving the reliability of the electric connection of the inner vias. Moreover, since the first and second electrical insulating layers serve to seal the first electronic component and the first inner vias as an electric connection component to be connected to this first electronic component, the second and third inner vias can be formed in the vicinity of the first electronic component.

The first to the third inner vias can be made of a conductive resin composition as a mixture of metallic particles and a thermosetting resin, for example. For the metal of the metallic particles, gold, silver, copper, nickel or the like can be used. These metals are preferred due to the high electric conductivity. Among them, copper is preferred particularly since copper has high electric conductivity and it resists migration. For the thermosetting resin, for example, an epoxy resin, a phenol resin, a cyanate resin and the like can be used. Among them, the epoxy resin is preferred due to the excellent heat resistance. The diameters of the first to the third inner vias are about 20 μm to about 300 μm, for example.

Next, a second electronic component embedded module of the present invention will be described. Further explanation is omitted for the contents overlapping with those of the first electronic component embedded module in the present invention.

The second electronic component embedded module of the present invention includes an electrical insulating substrate, and a first electronic component and a second electronic component embedded in this electrical insulating substrate. The electrical insulating substrate includes a first electrical insulating layer, a second electrical insulating layer, and a third electrical insulating layer sandwiched by the first and second electrical insulating layers. A first wiring pattern is disposed on a main face of the first electrical insulating layer opposite to the third electrical insulating layer. A second wiring pattern is disposed on a main face of the second electrical insulating layer opposite to the third electrical insulating layer.

For the first and second electronic components, any electronic components similar to the first electronic component used for the above-mentioned first electronic component embedded module of the present invention can be used. Similarly, for the first to third electrical insulating layers, any electrical insulating layers similar to the first and second electrical insulating layers used for the above-mentioned first electronic component embedded module can be used. Further, for the first and second wiring patterns, any wiring patterns similar to the first and second wiring patterns used for the above-mentioned electronic component embedded module of the present invention can be used. It is preferable that the first electrical insulating layer, the second electrical insulating layer and the third electrical insulating layer are formed of the same material, so that warping and cracks caused by the difference in the linear expansion coefficients of the respective layers can be prevented, thereby providing an electronic component embedded module with excellent reliability of electric connection.

And in the second electronic component embedded module of the present invention, the first electronic component is embedded in the third electrical insulating layer and also connected electrically to the first wiring pattern through first inner vias that penetrate the first electrical insulating layer, and the second electronic component is embedded in the third electrical insulating layer and also connected electrically to the second wiring pattern through second inner vias that penetrate the second electrical insulating layer. Thereby, there is no necessity of forming a gold bump, a solder bump or the like as a conventional electric connection component, and thus the process of manufacturing the electronic component embedded module can be simplified.

Furthermore, the first wiring pattern and the second wiring pattern are connected electrically to each other through third inner vias that penetrate the first electrical insulating layer, fourth inner vias that penetrate the third electrical insulating layer, and fifth inner vias that penetrate the second electrical insulating layer. The third inner vias, the fourth inner vias and the fifth inner vias are arranged continuously. Due to this configuration, as mentioned below, it is possible to form through holes in the first to third electrical insulating layers and fill these through holes with a conductive resin composition, before laminating the first electrical insulating layer, the second electrical insulating layer and the third electrical insulating layer Namely, since the through holes can be employed for space to provide inner vias, filling of the conductive resin composition can be carried out in a reliable manner. Therefore, the reliability of the electric connection of the inner vias can be improved. Moreover, since the first to third electrical insulating layers serve to seal the first and second electronic components and the first and second inner vias, the third to fifth inner vias can be formed in the vicinity of the first and second electronic components. The first to fifth inner vias used here can be the same as the first to third inner vias used for the above-mentioned first electronic component embedded module of the present invention.

Next, a method for manufacturing an electronic component embedded module of the present invention will be described. A first method for manufacturing an electronic component embedded module of the present invention denotes a method suitable for manufacturing the above-mentioned first electronic component embedded module of the present invention. Further explanation is omitted for the contents overlapping with those of the first electronic component embedded module in the present invention.

The first method for manufacturing an electronic component embedded module of the present invention includes the steps below. In the first step (a), first through holes and second through holes are formed in a first electrical insulating layer, and the first and second through holes are filled respectively with a first conductive resin composition. For forming the first and second through holes, processes such as punching and laser processing can be employed. For filling the through holes with the first conductive resin composition, for example, mask printing or the like can be employed. The first conductive resin composition used here can be a conductive resin composition prepared by mixing metallic particles and a thermosetting resin, for example. For the metals of the metallic particles, for example, gold, silver, copper, nickel and the like can be used. These metals are preferred due to the high electric conductivity. Among them, copper is preferred particularly since copper has high electric conductivity and it resists migration. For the thermosetting resin, for example, an epoxy resin, a phenol resin, a cyanate resin and the like can be used. Among them, the epoxy resin is preferred particularly due to the excellent heat resistance. In the next step (b), a first electrical insulating layer is laminated on a first base with a first wiring pattern formed thereon, so that the first wiring pattern and the first conductive resin composition are in contact with each other. And an electronic component is disposed on the first through holes filled with the first conductive resin composition, thereby forming a first laminate. Specific examples of the first base will be described later.

And in the step (c), third through holes are formed in the second electrical insulating layer and filled with a second conductive resin composition. For forming the third through holes, processes such as punching and laser processing can be employed. For filling the through holes with the second conductive resin composition, or example, mask printing can be employed. For the second conductive resin composition, any conductive resin composition substantially the same as the above-mentioned first conductive resin composition can be used. The step (c) can be carried out after/before the step (a). Alternatively, the step (a) can be carried out concurrently with the step (c).

In the next step (d), a second electrical insulating layer is laminated on the first laminate so that the third through holes filled with the second conductive resin composition are positioned on the second through holes filled with the first conductive resin composition, and a second base with a second wiring pattern formed thereon is laminated on the second electrical insulating layer so that the second wiring pattern and the second conductive resin composition are in contact with each other, thereby forming a second laminate. Specific examples of the second base will be described later.

In the next step (e), the second laminate is subjected to heat and pressure so that the electronic component is embedded in the second electrical insulating layer, the electronic component and the first wiring pattern are connected electrically to each other through first inner vias made of the first conductive resin composition, and the first wiring pattern and the second wiring pattern are connected electrically to each other through second inner vias made of the first conductive resin composition and third inner vias made of the second conductive resin composition. The condition for applying heat and pressure is that, for example, a pressure of 1 MPa to 20 MPa is applied while heating at a temperature of 150° C. to 260° C. In the above-mentioned process, since the through holes can be used as space for providing inner vias, filling of the conductive resin composition can be carried out in a reliable manner. Thereby, the reliability of the electric connection of the inner vias can be improved.

Next, a second method for manufacturing an electronic component embedded module of the present invention will be described. The second method for manufacturing an electronic component embedded module of the present invention denotes a method suitable for manufacturing the second electronic component embedded module of the present invention. Further explanation is omitted for the contents overlapping with the above explanations about the first and second electronic component embedded modules of the present invention.

In the second method for manufacturing an electronic component embedded module of the present invention includes, first, (I) first through holes and second through holes are formed in a first electrical insulating layer, and the first and second through holes are filled respectively with a first conductive resin composition. For forming the first and second through holes, processes such as punching and laser processing can be employed. For filling the through holes with the first conductive resin composition, for example, mask printing can be employed. The first conductive resin composition used here can be a conductive resin composition prepared by mixing metallic particles and a thermosetting resin, for example. For the metals of the metallic particles, for example, gold, silver, copper, nickel and the like can be used. These metals are preferred due to the high electric conductivity. Among them, copper is preferred particularly since copper has high electric conductivity and it resists migration. For the thermosetting resin, for example, an epoxy resin, a phenol resin, a cyanate resin and the like can be used. Among them, the epoxy resin is preferred particularly due to the excellent heat resistance.

In the next step (II), a first electrical insulating layer is laminated on a first base with a first wiring pattern formed thereon, so that the first wiring pattern and the first conductive resin composition are in contact with each other, and a first electronic component is disposed on the first through holes filled with the first conductive resin composition, thereby forming a first laminate. Specific examples of the first base will be described later.

In the next step (III), third through holes and fourth through holes are formed in the second electrical insulating layer, and the third and fourth through holes are filled respectively with a second conductive resin composition. For forming the third and fourth through holes, processes such as punching and laser processing can be employed. For filing the through holes with the second conductive resin composition, for example, mask printing can be employed. For the second conductive resin composition, any conductive resin composition substantially the same as the above-mentioned first conductive resin composition can be employed.

And in the step (IV), a second electrical insulating layer is laminated on the second base with a second wiring pattern formed thereon, so that the second wiring pattern and the second conductive resin composition are in contact with each other, and a second electronic component is disposed on third through holes filled with the second conductive resin composition, thereby forming a second laminate. Specific examples of the second base will be described later.

In the next step (V), fifth through holes are formed in a third electrical insulating layer, and the fifth through holes are filled with a third conductive resin composition. For forming the fifth through holes, processes such as punching and laser processing can be employed. For filling the through holes with the third conductive resin composition, for example, mask printing can be employed. For the third conductive resin composition, any conducive resin composition substantially same as the above-mentioned first conductive resin composition can be employed. The order of the above steps (I), (III) and (V) is not limited particularly. Alternatively, the steps (I), (III) and (V) can be carried out concurrently.

In the next step (VI), the third electrical insulating layer is sandwiched by the first and second laminates so that the fifth through holes filled with the third conductive resin composition are positioned between the second through holes filled with the first conductive resin composition and the fourth through holes filled with the second conductive resin composition, thereby forming a third laminate.

In the next step (VII), the third laminate is subjected to heat and pressure so that the first and second electronic components are embedded in the third electrical insulating layer; the first electronic component and the first wiring pattern are connected electrically to each other through first inner vias made of the first conductive resin composition; and, the second electronic component and the second wiring pattern are connected electrically to each other through the second inner vias made of the second conductive resin composition; and the first wiring pattern and the second wiring pattern are connected electrically to each other through third inner vias made of the first conductive resin composition, fourth inner vias made of the third conductive resin composition, and fifth inner vias made of the second conductive resin composition. The condition for applying heat and pressure is that, for example, a pressure of 1 MPa to 20 MPa is applied while heating at a temperature of 150° C. to 260° C. In the above-mentioned process, since the through holes can be used as space for providing inner vias, filling of the conductive resin composition can be carried out in a reliable manner. Thereby, the reliability of the electric connection of the inner vias can be improved.

Hereinafter, embodiments of the present invention will be described with reference to the attached figures. Regarding the figures for reference, for the purpose of providing brief and concise explanation, components having the substantially same functions may be indicated with the identical reference numbers to avoid the duplicated explanation.

### FIRST EMBODIMENT

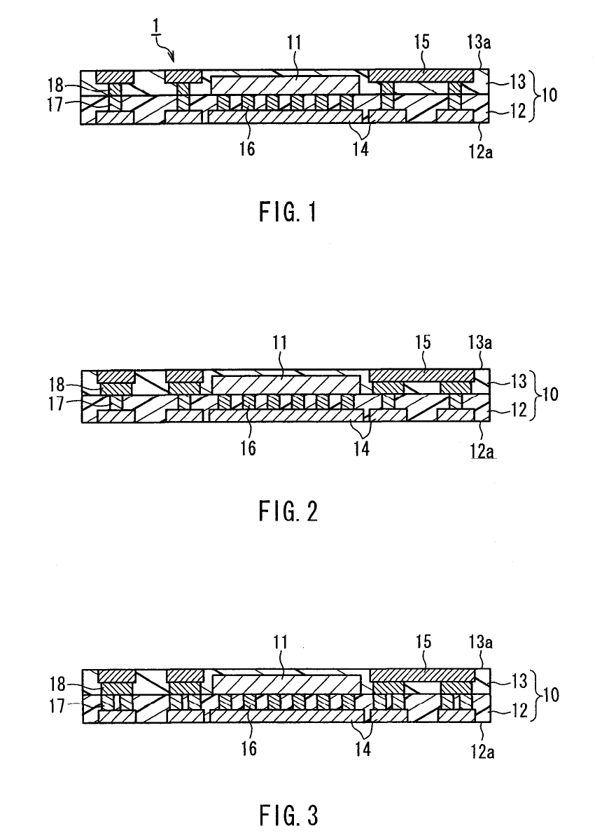

First, an electronic component embedded module according to a First Embodiment of the present invention will be described. FIG. 1 is a cross-sectional view showing an electronic component embedded module according to First Embodiment of the present invention.

As shown in FIG. 1, an electronic component embedded module 1 includes an electrical insulating substrate 10 and a first electronic component 11 embedded in the electrical insulating substrate 10. The electrical insulating substrate 10 includes a first electrical insulating layer 12 and a second electrical insulating layer 13 laminated on the first electrical insulating layer 12. A first wiring pattern 14 is disposed on a main face 12a of the first electrical insulating layer 12 opposite to the second electrical insulating layer 13. A second wiring pattern 15 is disposed on a main face 13a of the second electrical insulating layer 13 opposite to the first electrical insulating layer 12. It is preferable that the thickness of the first electrical insulating layer 12 is about 20 to 200 μm, for example. It is preferable that the thickness of the second electrical insulating layer 13 is about 20 to 200 μm, for example.

The first electronic component 11 is embedded in the second electrical insulating layer 13 and connected electrically to the first wiring pattern 14 through first inner vias 16 that penetrate the first electrical insulating layer 12. As a result, there is no necessity of forming a gold bump, a solder bump or the like as a conventional electric connection component, and thus the process of manufacturing the electronic component embedded module 1 can be simplified.

The first wiring pattern 14 and the second wiring pattern 15 are connected electrically to each other through second inner vias 17 that penetrate the first electrical insulating layer 12 and third inner vias 18 that penetrate the second electrical insulating layer 13. The second inner vias 17 and the third inner vias 18 are arranged continuously. Due to this configuration, as mentioned later, it is possible to form through holes in the first and second electrical insulating layers 12, 13 and to fill these through holes with conductive resin compositions, before laminating the first electrical insulating layer 12 and the second electrical insulating layer 13. Namely, since through holes can be employed as space for providing inner vias, filling of the conductive resin composition can be carried out in a reliable manner. And thus, the reliability of the electric connection of the inner vias can be improved.

In the electronic component embedded module 1, the first and second electrical insulating layers 12, 13 serve to seal the first electronic component 11 and the first inner vias 16, and thus the second and third inner vias 17, 18 can be formed in the vicinity of the first electronic component 11. Further, since a gold bump or a solder bump as a conventional electric connection component is not used, the thickness of the first electrical insulating layer 12 can be set arbitrarily. Therefore, for example, it is possible to form second inner vias 17 with a low aspect ratio.

In a case where an electrical insulating layer including an inorganic filler is used for the second electrical insulating layer 13, even when a crack develops between the back face of the first electronic component 11 and the second electrical insulating layer 13, the crack can be prevented from spreading to the third inner vias 18. Thereby, the reliability of the electric connection of the third inner vias 18 can be ensured.

Furthermore in the electronic component embedded module 1, the exposed face of the first electrical insulating layer 12 and the outermost surface of the first wiring pattern 14 are formed substantially flush with each other, and the exposed face of the second electrical insulating layer 13 and the outermost surface of the second wiring pattern 15 are formed substantially flush with each other. Thereby, the thickness of the electronic component embedded module 1 can be reduced easily. The method for manufacturing the electronic component embedded module I will be described later.

Next, a variation of the electronic component embedded module 1 according to First Embodiment of the present invention will be described with reference to FIGS. 2 to 5.

The electronic component embedded module of the present invention can be an electronic component embedded module as shown in FIG. 2, where the diameter of the third inner vias 18 is larger than the diameter of the second inner vias 17. Accordingly, in the process of manufacturing the electronic component embedded module, the third inner vias 18 and the second inner vias 17 can be aligned easily, thereby providing an electronic component embedded module with excellent reliability of electric connection.

The electronic component embedded module of the present invention can be an electronic component embedded module as shown in FIG. 3, where a plurality of (two in FIG. 3) second inner vias 17 are connected to one of the third inner vias 18. Accordingly, contacts between the third inner vias 18 and the second inner vias 17 are increased, thereby decreasing a risk of rupture in the electric connection between the third inner vias 18 and the second inner vias 17.

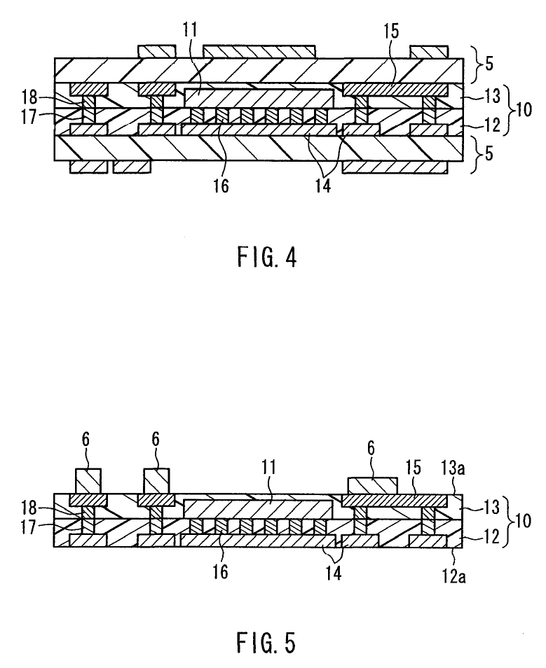

The electronic component embedded module of the present invention can have a configuration as shown in FIG. 4, where the electronic component embedded module 1 shown in FIG. 1 is sandwiched by two printed circuit boards 5,5. Accordingly, the mechanical strength of the electronic component embedded module is improved to provide an electronic component embedded module with excellent reliability of the electric connection. In FIG. 4, an electronic component can be mounted on a wiring pattern formed on the printed circuit board 5 (i.e., the exposed wiring pattern).

As shown in FIG. 5, the electronic component embedded module of the present invention can include further a second electronic component 6 mounted on at least one main face (the second wiring pattern 15 in FIG. 5) of the electrical insulating substrate 10. The thus provided electronic component embedded module can have electronic components mounted at a high density. For the second electronic component 6, for example, an active component or a passive component can be used. For the active component, for example, semiconductor elements such as a transistor, IC and LSI can be used. For the passive component, an inductor, a capacitor, a resistor or the like can be used.

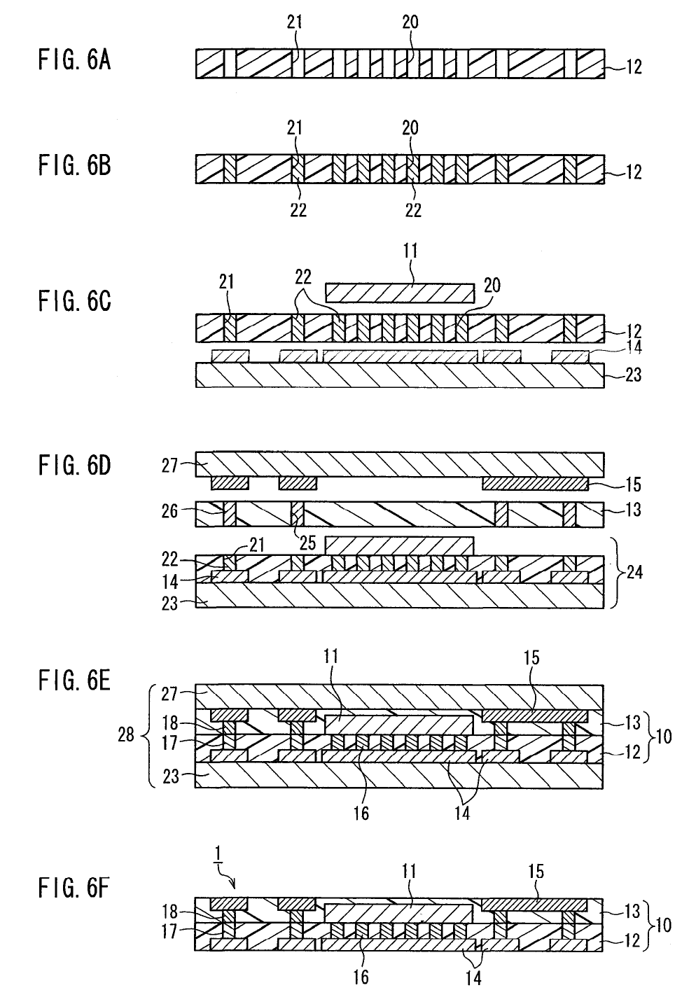

Next, a preferred method for manufacturing the electronic component embedded module 1 according to First Embodiment will be described. FIGS. 6A to 6F for reference are cross-sectional views showing respective steps of the manufacturing method.

First, as shown in FIG. 6A, first through holes 20 and second through holes 21 are formed in the first electrical insulating layer 12. The first through holes 20 and the second through holes 21 can be formed by laser processing for example. The laser processing is preferred since through holes can be formed with a fine pitch and no scrapings will be generated. For the laser to be used for the laser processing, a carbon dioxide gas laser or an excimer laser is used preferably from the viewpoint of processability. It is preferable that the first through holes 20 and the second through holes 21 are formed by an identical method (for, example by laser processing with a carbon dioxide gas laser) since the steps can be simplified.

Next, as shown in FIG. 6B, the first through holes 20 and the second through holes 21 are filled respectively with a first conductive resin composition 22 by mask printing, for example.

Next, as shown in FIG. 6C, on a first base 23 with the first wiring pattern 14 formed thereon, the first electrical insulating layer 12 is laminated so that the first wiring pattern 14 and the first conductive resin composition 22 are in contact with each other, and a first electronic component 11 is disposed on the first through holes 20 filled with the first conductive resin composition 22, which are temporarily tacked by heating at relatively low temperature so as to form a first laminate 24 (see FIG. 6D). The heating temperature is not limited particularly as long as the first electrical insulating layer 12 is not cured, for example, temperature in a range of about 50° C. to about 130° C. For the first base 23, a peelable carrier can be used. For the specific example, a metal foil coated with a peeling layer can be used, and the peeling layer is an organic film such as a fluorine resin film. The examples include a copper foil with a peeling layer and an aluminum foil with a peeling layer. Alternatively, the first wiring pattern 14 of a copper foil can be formed on such a peelable carrier through a metal plating layer such as a Ni plating layer. The first wiring pattern 14 can be formed, for example, by adhering a copper foil on a peelable carrier and subjecting to a photolithography process and an etching process.

Subsequently, third through holes 25 are formed in the second electrical insulating layer 13 by the same method as in FIGS. 6A and 6B, and the third through holes 25 are filled with a second conductive resin composition 26 (see FIG. 6D). And, as shown in FIG. 6D, the second electrical insulating layer 13 are laminated on the first laminate 24 so that the third through holes 25 filled with the second conductive resin composition 26 are positioned on the second through holes 21 filled with the first conductive resin composition 22, and a second base 27 with a second wiring pattern 15 formed thereon is laminated on the second electrical insulating layer 13 so that a second wiring pattern 15 and the second conductive resin composition 26 are in contact with each other, thereby forming a second laminate 28 as shown in FIG. 6E. For the second base 27, the above-mentioned metal foil with a peeling layer can be used, for example. And this second laminate 28 is subjected to heat and pressure so that the first electronic component 11 is embedded in the second electrical insulating layer 13, the first electronic component 11 and the first wiring pattern 14 are connected electrically to each other through first inner vias 16 made of the first conductive resin composition 22, and the first wiring pattern 14 and the second wiring pattern 15 are connected electrically to each other through second inner vias 17 made of the first conductive resin composition 22 and also third inner vias 18 made of the second conductive resin composition 26.

Subsequently, the first base 23 and the second base 27 are peeled to provide the electronic component embedded module 1 in the finished form as shown in FIG. 6F.

In the above-mentioned manufacturing method, the second and third through holes 21, 25 are formed so that the diameter of the third through holes 25 will be larger than the diameter of the second through holes 21, thereby the electronic component embedded module as shown in FIG. 2 is obtained. When the second and third through holes 21, 25 are formed so that at least two of the second through holes 21 correspond to one of the third through holes 25, the electronic component embedded module shown in FIG. 3 will be obtained.

Alternatively in the above-mentioned manufacturing method, the electronic component embedded module as shown in FIG. 4 will be obtained by using printed circuit boards in place of the peelable carriers. In this case, the step of peeling off the peelable carriers is not required. Alternatively, the electronic component embedded module as shown in FIG. 5 will be obtained by mounting the second electronic component 6 on the second wiring pattern 15 of the electronic component embedded module 1 shown in FIG. 6F.

### SECOND EMBODIMENT

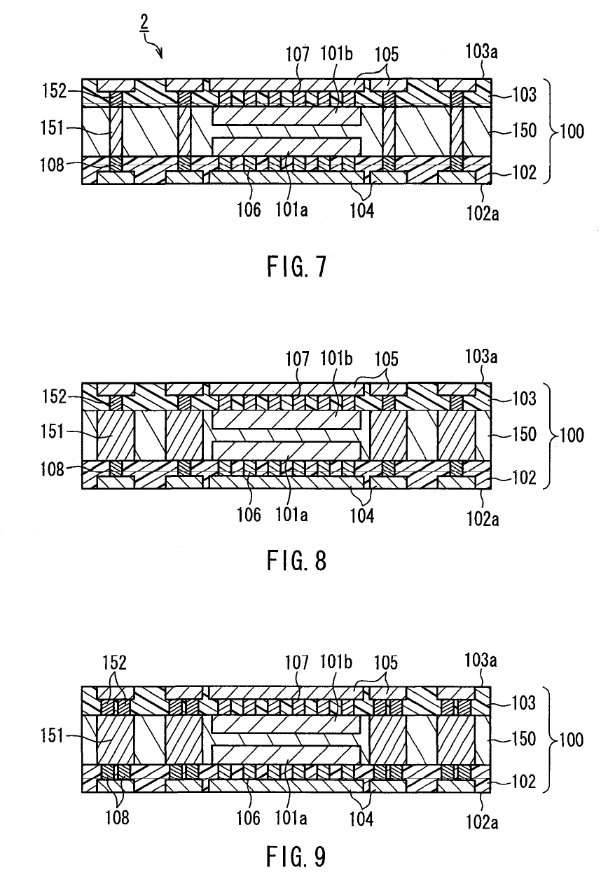

The following description is about an electronic component embedded module according to Second Embodiment of the present invention. FIG. 7 is a cross-sectional view showing the electronic component embedded module according to Second Embodiment.

As shown in FIG. 7, an electronic component embedded module 2 includes an electrical insulating substrate 100, and a first electronic component 101a and a second electronic component 101b embedded in the electrical insulating substrate 100. The electrical insulating substrate 100 includes a first electrical insulating layer 102, a second electrical insulating layer 103, and a third electrical insulating layer 150 sandwiched by the first and second electrical insulating layers 102, 103. A first wiring pattern 104 is disposed on a main face 102a of the first electrical insulating layer 102 opposite to the third electrical insulating layer 150. A second wiring pattern 105 is disposed on a main face 103a of the second electrical insulating layer 103 opposite to the third electrical insulating layer 150. Here, the thickness of the first and second electrical insulating layers 102, 103 is about 20 to about 200 μm for example, though there is no particular limitation. The thickness of the third electrical insulating layer 150 is about 30 to about 400 μm for example, though there is no particular limitation.

The first electronic component 101a is embedded in the third electrical insulating layer 150 and connected electrically to the first wiring pattern 104 through first inner vias 106 that penetrate the first electrical insulating layer 102. The second electronic component 101b is embedded in the third electrical insulating layer 150 and connected electrically to the second wiring pattern 105 through second inner vias 107 that penetrate the second electrical insulating layer 103. The first wiring pattern 104 and the second wiring pattern 105 are connected electrically to each other through third inner vias 108 that penetrate the first electrical insulating layer 102, fourth inner vias 151 that penetrate the third electrical insulating layer 150, and fifth inner vias 152 that penetrate the second electrical insulating layer. The third inner vias 108, the fourth inner vias 151 and the fifth inner vias 152 are arranged continuously. Due to the above-described configuration, it is possible to provide an electronic component embedded module that can provides effects similar to those of the electronic component embedded module 1 (see FIG. 1) according to the above-mentioned First Embodiment, and that has electronic components mounted at a higher density.

Subsequently, a variation of the electronic component embedded module according to Second Embodiment of the present invention will be described below with reference to FIGS. 8 to 11.

The electronic component embedded module of the present invention can be an electronic component embedded module as shown in FIG. 8, where the diameter of the fourth inner vias 151 is larger than the diameter of the third inner vias 108 and the diameter of the fifth inner vias 152. Accordingly, in the process of manufacturing the electronic component embedded module, the third inner vias 108, the fourth inner vias 151 and the fifth inner vias 152 can be aligned easily, thereby an electronic component embedded module with excellent reliability of electric connection can be provided.

The electronic component embedded module of the present invention can be an electronic component embedded module as shown in FIG. 9, where a plurality (two in FIG. 9) of the third inner vias 108 and a plurality (two in FIG. 9) of the fifth inner vias 152 are connected to one of the fourth inner vias 151. Accordingly, the contacts between the fourth inner vias 151 and the third inner vias 108 and also the contacts between the fourth inner vias 151 and the fifth inner vias 152 are increased, and thus the risk of ruptures in the electric connection between the fourth inner vias 151 and the third inner vias 108 and also in the electric connection between the fourth inner vias 151 and the fifth inner vias 152 can be reduced.

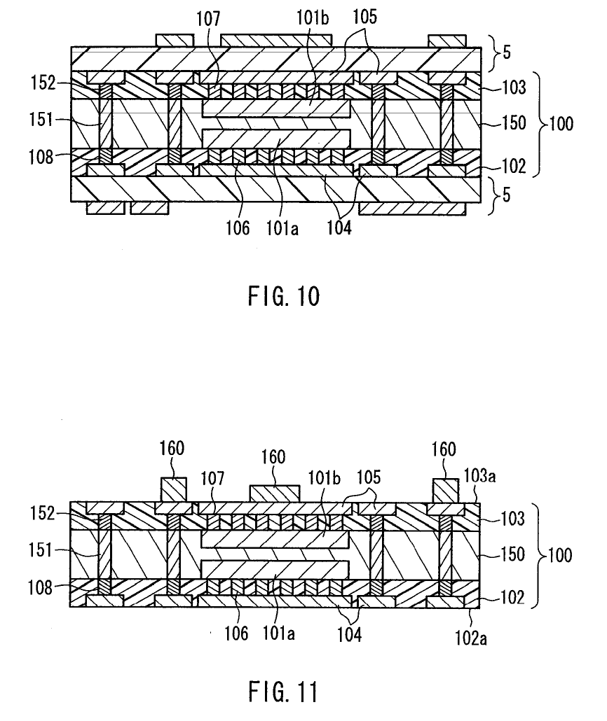

As shown in FIG. 10, the electronic component embedded module of the present invention can be configured by sandwiching the electronic component embedded module 2 shown in FIG. 7 with two printed circuit boards 5, 5. Accordingly, the mechanical strength of the electronic component embedded module is enhanced, and thus an electronic component embedded module with excellent reliability of electric connection can be provided.

The electronic component embedded module of the present invention can be an electronic component embedded module as shown in FIG. 11, which further includes a third electronic component 160 mounted on at least one main face (the second wiring pattern 105 in FIG. 11) of the electrical insulating substrate 100. Accordingly, an electronic component embedded module having electronic components mounted at a high density can be provided. For the third electronic component 160, for example, an active component or a passive component can be used. For the active component, for example, semiconductor elements such as a transistor, IC and LSI can be used. For the passive element, for example, an inductor, a capacitor, a resistor and the like can be used.

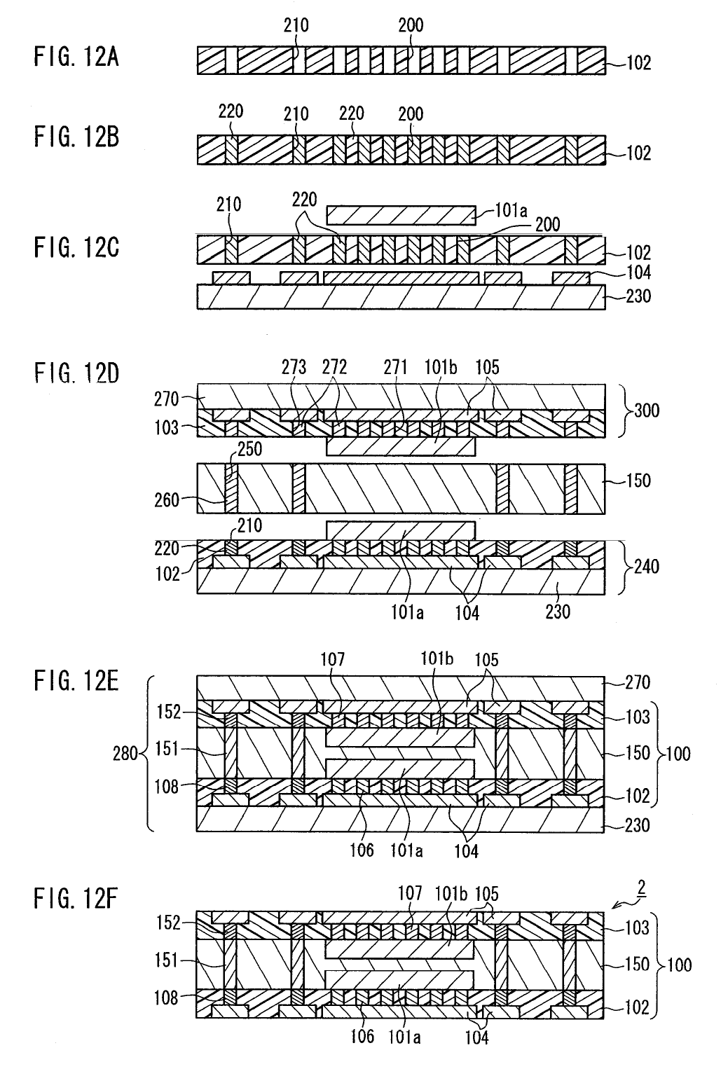

The following description is about a preferred method for manufacturing the electronic component embedded module 2 according to Second Embodiment of the present invention. FIGS. 12A-12F for reference are cross-sectional views showing the respective steps of the manufacturing method.

First, as shown in FIG. 12A, first through holes 200 and second through holes 210 are formed in the first electrical insulating layer 102. The first through holes 200 and the second through holes 210 can be formed by laser processing, for example. The laser processing is preferred since through holes can be formed with a fine pitch and no scrapings will be generated. For the laser to be used for the laser processing, from the viewpoint of processability, a carbon dioxide gas laser or an excimer laser is used preferably. It is preferable that the first through holes 200 and the second through holes 210 are formed by an identical method for example, by laser processing with a carbon dioxide gas laser) since the steps can be simplified.

Next, as shown in FIG. 12B, the first through holes 200 and the second through holes 210 are filled respectively with a first conductive resin composition 220 by mask printing for example.

Next, as shown in FIG. 12C, on a first base 230 with the first wiring pattern 104 formed thereon, the first electrical insulating layer 102 is laminated so that the first wiring pattern 104 and the first conductive resin composition 220 are in contact with each other, and the first electronic component 101a is disposed on the first through holes 200 filled with the first conductive resin composition 220, which are temporarily tacked by heating at relatively low temperature so as to form a first laminate 240 (see FIG. 12D). The heating temperature is not limited particularly as long as the first electrical insulating layer 102 is not cured, for example, a temperature in a range of about 50° C. to about 130° C. For the first base 230, the above-mentioned metal foil with a peeling layer can be used for example.

Subsequently, third through holes 271 and fourth through holes 273 are formed in the second electrical insulating layer 103 by the same method as in FIGS. 12A and 12B, and the third through holes 271 and the fourth through holes 273 are filled respectively with a second conductive resin composition 272 (see FIG. 12D) by mask printing or the like. And, by the same method as shown in FIG. 12C, the second electrical insulating layer 103 is laminated on the second base 270 with the second wiring pattern 105 formed thereon so that the second wiring pattern 105 and the second conductive resin composition 272 are in contact with each other, and a second electronic component 101b is disposed on the third through holes 271 filled with the second conductive resin composition 272, which are tacked by heating at relatively low temperature so as to form a second laminate 300 (see FIG. 12D). For the second base 270 the above-mentioned metal foil with a peeling layer can be used for example. By the method as shown in FIGS. 12A and 12B, the fifth through holes 250 are formed in the third electrical insulating layer 150, and the fifth through holes 250 are filled with a third conductive resin composition 260 (see FIG. 12D).

Next, as shown in FIG. 12D, the third electrical insulating layer 150 is sandwiched by the first and second laminates 240, 300 so that the fifth through holes 250 filled with the third conductive resin composition 260 are positioned between the second through holes 210 filled with the first conductive resin composition 220 and the fourth through holes 273 filled with the second conductive resin composition 272, thereby forming a third laminate 280 shown in FIG. 12E. Then, the third laminate 280 is subjected to heat and pressure, and thus the first and second electronic components 101a, 101b are embedded in the third electrical insulating layer 150; the first electronic component 101a and the first wiring pattern 104 are connected electrically to each other through first inner vias 106 made of the first conductive resin composition 220; and, the second electronic component 101b and the second wiring pattern 105 are connected electrically to each other through second inner vias 107 made of the second conductive resin composition 272; the first wiring pattern 104 and the second wiring pattern 105 are connected electrically to each other through third inner vias 108 made of the first conductive resin composition 220, fourth inner vias 151 made of the third conductive resin composition 260 and fifth inner vias 152 made of the second conductive resin composition 272.

Subsequently, the first base 230 and the second base 270 are peeled off to provide the electronic component embedded module 2 in a finished form shown in FIG. 12F.

In the above-mentioned manufacturing method, the second, fourth and fifth through holes 210, 273, 250 are formed so that the diameter of the fifth through holes 250 is larger than the diameter of the second through holes 210 and the diameter of the fourth through holes 273, and thereby the electronic component embedded module shown in FIG. 8 is obtained. Alternatively, the second, fourth and fifth through holes 210, 273, 250 are formed so that at least two of the second through holes 210 and at least two of the fourth through holes 273 correspond respectively to one of the fifth through holes 250, and thereby the electronic component embedded module shown in FIG. 9 is obtained.

In the above-mentioned manufacturing method, the electronic component embedded module shown in FIG. 10 can be obtained by using printed circuit boards in place of the peelable carriers. In this case, the step of peeling off the peelable carriers is not required. Further, the electronic component embedded module shown in FIG. 11 can be obtained by mounting a third electronic component 160 on the second wiring pattern 105 of the electronic component embedded module 2 shown in FIG. 12F.

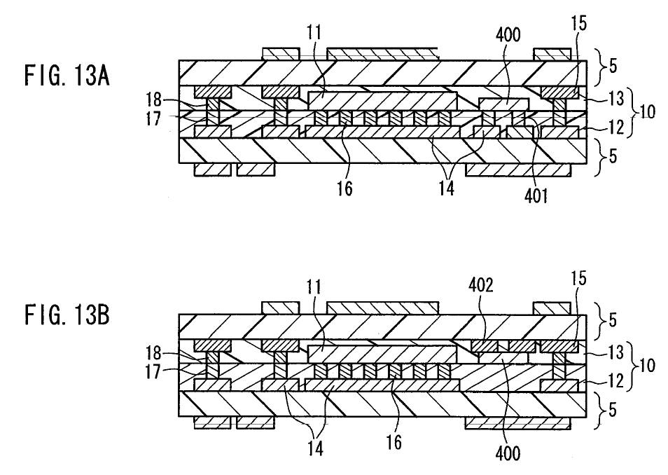

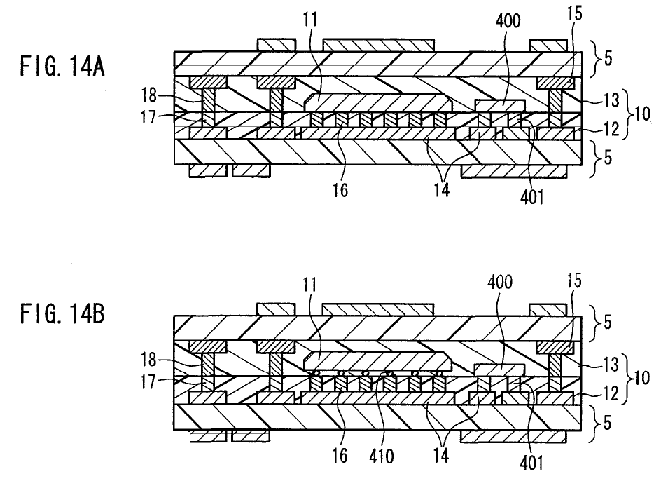

It should be noted that the present invention will not be limited to the above-mentioned embodiments of the present invention. For example, as shown in FIGS. 13A and 13B, the electronic component embedded module can include a embedded passive component 400. In each of FIGS. 13A and 13B, the passive component 400 is embedded in the electrical insulating substrate 10 of the above-mentioned electronic component embedded modes own in FIG. 4. In FIG. 13A, the passive component 400 is connected electrically to the first wiring pattern 4 through a via conductor 4. In FIG. 13B, the passive component 400 is mounted on a printed circuit board 5 through a solder 402. For the first electronic components 11 in FIGS. 13A and 13B, active components can be used respectively.

Furthermore, as shown in FIGS. 14A and 14B, a semiconductor package can be used for the first electronic component 11. In FIG. 14A, the semiconductor package is mounted by LGA (and grid array). In FIG. 14B, the semiconductor package is mounted by BGA (ball grid array). Numeral 410 in FIG. 14B denotes a solder ball.

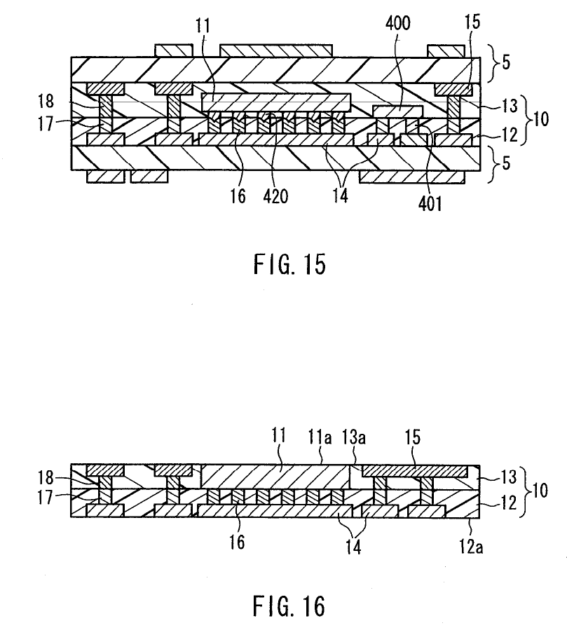

As shown in FIG. 15, it is also possible that the first electronic component 11 is connected electrically to the first inner vias 16 through a bump 420. In FIG. 15, the bump 420 is embedded partly in the first inner vias 16. In this case, the reliability of the electric connection between the bump 420 and the first inner vias 16 is improved further due to the anchoring effect.

Alternatively, as shown in FIG. 16, a main face 11a of the first electronic component 11 can be exposed. According to this configuration, the overall thickness of the electronic component embedded module can be reduced, and heat generated by the first electronic component 11 can be radiated efficiently.

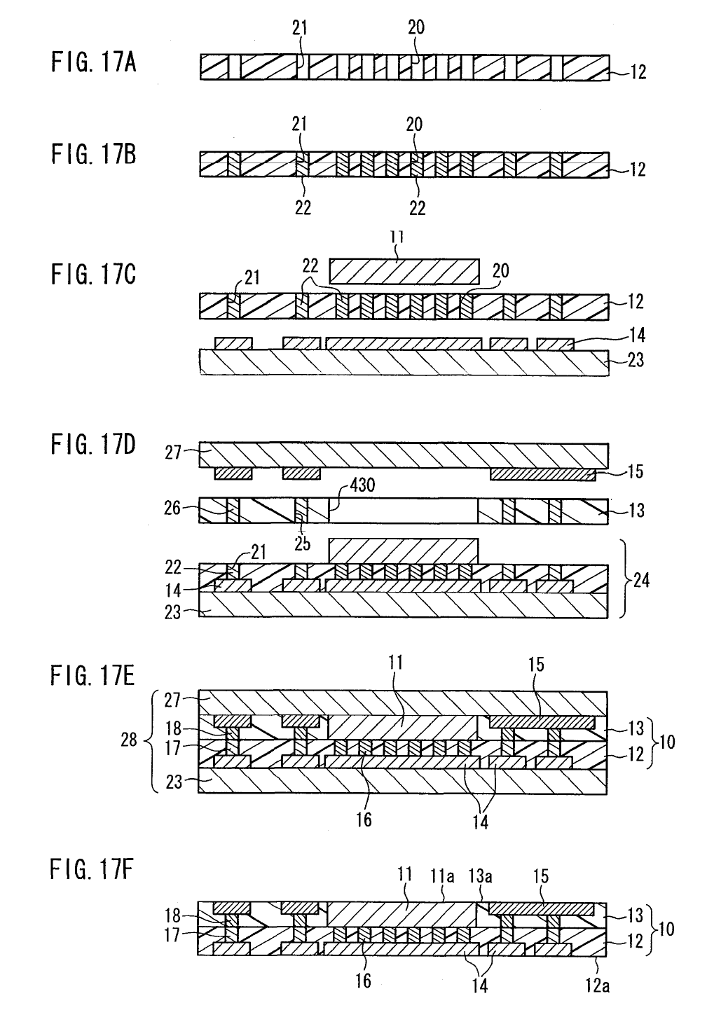

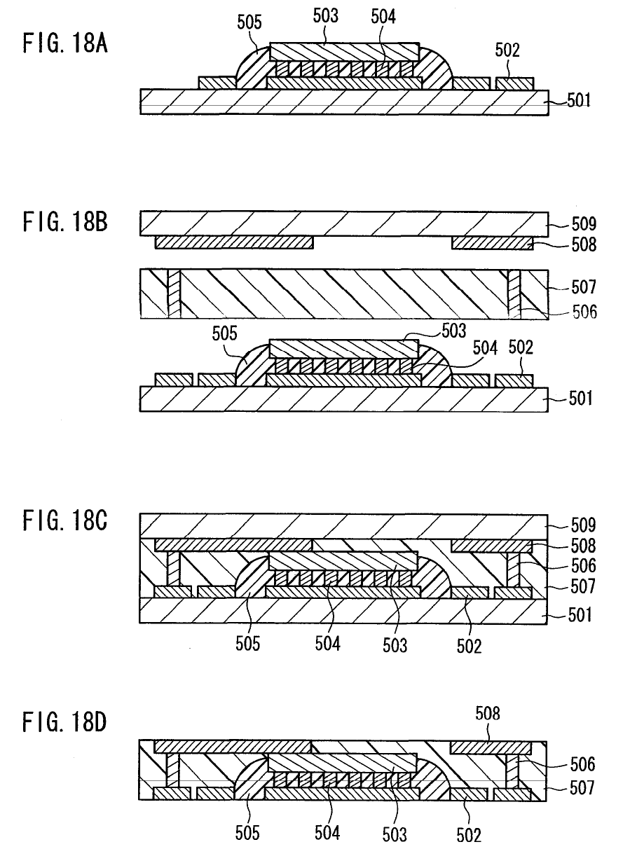

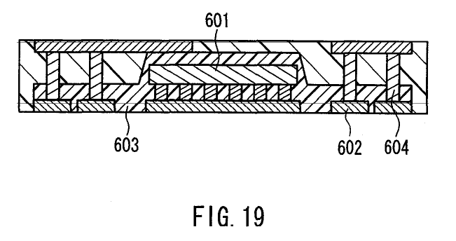

The following description is about a preferred method for manufacturing the above-mentioned electronic component embedded module shown in FIG. 16. The referred FIGS. 17A-17F are cross-sectional views showing the respective steps of the manufacturing method.

First, as shown in FIG. 17A, first through holes 20 and second through holes 21 are formed in the first electrical insulating layer 12. The first through holes 20 and the second through holes 21 can be formed by laser processing for example. The laser processing is preferred since through holes can be formed with a fine pitch and no scrapings will be generated. For the laser to be used for the laser processing, from the viewpoint of processability, a carbon dioxide gas laser or an excimer laser is used preferably. It is preferable that the first through holes 20 and the second through holes 21 are formed by an identical method (for example, by laser processing with a carbon dioxide gas laser) since the steps can be simplified.

Next, as shown in FIG. 17B, the first through holes 20 and the second through holes 21 are filled respectively with a first conductive resin composition 22 by mask printing for example.

Next, as shown in FIG. 17C, on a first base 23 with the first wiring pattern 14 formed thereon, the first electrical insulating layer 12 is laminated so that the first wiring pattern 14 and the first conductive resin composition 22 are in contact with each other, and the first electronic component 11 is disposed on the first through holes 20 filled with the first conductive resin composition 22, which are temporarily tacked by heating at relatively low temperature so as to form a first laminate 24 (see FIG. 17D). The heating temperature is not limited particularly as long as the first electrical insulating layer 12 is not cured, for example, a temperature in a range of about 50° C. to about 130° C. For the first base 23, the above-mentioned metal foil with a peeling layer can be used.

Subsequently, by the same method as shown in FIGS. 17A and 17B, third through holes 25 are formed in the second electrical insulating layer 13, and the third through holes 25 are filled with a second conductive resin composition 26 (see FIG. 17D). And a cavity 430 to house the first electronic component 11 is formed to penetrate the second electrical insulating layer 13. The cavity 430 can be formed by punching, laser processing or the like. And as shown in FIG. 17D, the second electrical insulating layer 13 is laminated on the first laminate 24 so that the third through holes 25 filled with the second conductive resin composition 26 are positioned on the second through holes 21 filled with the first conductive resin composition 22, and a second base 27 with a second wiring pattern 15 formed thereon is laminated on the second electrical insulating layer 13 so that the second wiring pattern 15 and the second conductive resin composition 26 are in contact with each other, thereby forming a second laminate 28 as shown in FIG. 17E. At this time, the first electronic component 11 is aligned to be housed in the cavity 430. For the second base 27, the above-mentioned metal foil with a peeling layer can be used, for example. And this second laminate 28 is subjected to heat and pressure so that the first electronic component 11 is embedded in the second electrical insulating layer 13, the first electronic component 11 and the first wiring pattern 14 are connected electrically to each other through first inner vias 16 made of the first conductive resin composition 22, and the first wiring pattern 14 and the second wiring pattern 15 are connected electrically to each other through second inner vias 17 made of the first conductive resin composition 22 and third inner via 18 made of the second conductive resin composition 26.

Subsequently, the first base 23 and the second base 27 are peeled off to provide the electronic component embedded module 1 in a finished form as shown in FIG. 17F.

### INDUSTRIAL APPLICABILITY

According to the present invention, an electronic component embedded module with excellent reliability of electric connection of its inner vias can be provided.

1. An electronic component embedded module comprising an electrical insulating substrate and a first electronic component embedded in the electrical insulating substrate,
the electrical insulating substrate comprising a first electrical insulating layer and a second electrical insulating layer laminated on the first electrical insulating layer,
a first wiring pattern disposed on a main face of the first electrical insulating layer opposite to the second electrical insulating layer,
a second wiring pattern disposed on a main face of the second electrical insulating layer opposite to the first electrical insulating layer,
the first electronic component being embedded in the second electrical insulating layer and connected electrically to the first wiring pattern through first inner vias that penetrate the first electrical insulating layer,
the first wiring pattern and the second wiring pattern being connected electrically to each other through second inner vias that penetrate the first electrical insulating layer and third inner vias that penetrate the second electrical insulating layer, and
the second inner vias and the third inner vias being arranged continuously.

2. The electronic component embedded module according to claim 1, wherein the diameter of the third inner vias is larger than the diameter of the second inner vias.

3. The electronic component embedded module according to claim 2, wherein at least two of the second inner vias are connected to one of the third inner vias.

4. The electronic component embedded module according to claim 1, further comprising two printed circuit boards for sandwiching the electrical insulating substrate.

5. The electronic component embedded module according to claim 1, further comprising a second electronic component mounted on at least one main face of the electrical insulating substrate.

6. The electronic component embedded module according to claim 1, wherein a main face of the first electronic component is exposed.

7. An electronic component embedded module comprising: an electrical insulating substrate, and a first electronic component and a second electronic component that are embedded in the electrical insulating substrate,
the electrical insulating substrate comprising a first electrical insulating layer, a second electrical insulating layer, and a third electrical insulating layer that is sandwiched by the first and second electrical insulating layers,
a first wiring pattern disposed on a main face of the first electrical insulating layer opposite to the third electrical insulating layer,
a second wiring pattern disposed on a main face of the second electrical insulating layer opposite to the third electrical insulating layer,
the first electronic component being embedded in the third electrical insulating layer and connected electrically to the first wiring pattern through first inner vias that penetrate the first electrical insulating layer,
the second electronic component being embedded in the third electrical insulating layer and connected electrically to the second wiring pattern through second inner vias that penetrate the second electrical insulating layer,
the first wiring pattern and the second wiring pattern being connected electrically to each other through third inner vias that penetrate the first electrical insulating layer, fourth inner vias that penetrate the third electrical insulating layer, and fifth inner vias that penetrate the second electrical insulating layer, and
the third inner vias, the fourth inner vias and the fifth inner vias being arranged continuously.

8. The electronic component embedded module according to claim 7, wherein the diameter of the fourth inner vias is larger than the diameter of the third inner vias and the diameter of the fifth inner vias.

9. The electronic component embedded module according to claim 8, wherein at least two of the third inner vias and at least two of the fifth inner vias are connected to one of the fourth inner vias.

10. The electronic component embedded module according to claim 7, further comprising two printed circuit boards for sandwiching the electrical insulating substrate.

11. The electronic component embedded module according to claim 7, further comprising a third electronic component mounted on at least one main face of the electrical insulating substrate.

12. A method for manufacturing an electronic component embedded module, the method comprising the steps of:
(a) forming first through holes and second through holes in a first electrical insulating layer, and filling the first and second through holes respectively with a first conductive resin composition,
(b) laminating the first electrical insulating layer on a first base with a first wiring pattern formed thereon so that the first wiring pattern and the first conductive resin composition are in contact with each other, and disposing an electronic component on the first through holes filled with the first conductive resin composition, thereby forming a first laminate,
(c) forming third through holes in a second electrical insulating layer and filling the third through holes with a second conductive resin composition,
(d) laminating the second electrical insulating layer on the first laminate so as to position the third through holes filled with the second conductive resin composition on the second through holes filled with the first conductive resin composition, and laminating a second base with a second wiring pattern formed thereon on the second electrical insulating layer so that the second wiring pattern and the second conductive resin composition are in contact with each other, thereby forming a second laminate, and
(e) subjecting the second laminate to heat and pressure so that the electronic component is embedded in the second electrical insulating layer, the electronic component and the first wiring pattern are connected electrically to each other through first inner vias made of the first conductive resin composition, and the first wiring pattern and the second wiring pattern are connected electrically to each other through second inner vias made of the first conductive resin composition and third inner vias made of the second conductive resin composition.

13. The method for manufacturing an electronic component embedded module according to claim 12, wherein in the steps (a) and (c), the second and the third through holes are formed so that the diameter of the third through holes is larger than the diameter of the second through holes.

14. The method for manufacturing an electronic component embedded module according to claim 13, wherein the second through holes and the third through holes are formed so that at least two of the second through holes correspond to one of the third through holes.

15. The method for manufacturing an electronic component embedded module according to claim 12, wherein the first and second bases are peelable carriers, and the method further comprises a step of peeling off the peelable carriers subsequent to the step (e).

16. A method for manufacturing an electronic component embedded module, the method comprising the steps of:
(I) forming first through holes and second through holes in a first electrical insulating layer, and filing the first and second through holes respectively with a first conductive resin composition,
(II) laminating the first electrical insulating layer on a first base with a first wiring pattern formed thereon so that the first wiring pattern and the first conductive resin composition are in contact with each other, and disposing a first electronic component on the first through holes filled with the first conductive resin composition, thereby forming a first laminate,
(III) forming third through holes and fourth through holes in a second electrical insulating layer, and filling the third and fourth through holes respectively with a second conductive resin composition,
(IV) laminating the second electrical insulating layer on a second base with a second wiring pattern formed thereon so that the second wiring pattern and the second conductive resin composition are in contact with each other, and disposing a second electronic component on the third through holes filled with the second conductive resin composition, thereby forming a second laminate,
(V) forming fifth through holes in a third electrical insulating layer and filing the fifth through holes with a third conductive resin composition,
(VI) sandwiching the third electrical insulating layer with the first and second laminates so that the fifth through holes filled with the third conductive resin composition are positioned between the second through holes filled with the first conductive resin composition and the fourth through holes filled with the second conductive resin composition, thereby forming a third laminate, and
(VII) subjecting the third laminate to heat and pressure so that the first and second electronic components are embedded in the third electrical insulating layer; the first electronic component and the first wiring pattern are connected electrically to each other through first inner vias made of the first conductive resin composition; the second electronic component and the second wiring pattern are connected electrically to each other through second inner vias made of the second conductive resin composition; and the first wiring pattern and the second wiring pattern are connected electrically to each other through third inner vias made of the first conductive resin composition, fourth inner vias made of the third conductive resin composition, and fifth inner vias made of the second conductive resin composition.

17. The method for manufacturing an electronic component embedded module according to claim 16, wherein the second, fourth and fifth through holes are formed so that the diameter of the fifth through holes is larger than the diameter of the second through holes and the diameter of the fourth through holes.

18. The method for manufacturing an electronic component embedded module according to claim 17, wherein the second, fourth and fifth through holes are formed so that at least two of the second through holes and at least two of the fourth through holes correspond respectively to one of the fifth through holes.

19. The method for manufacturing an electronic component embedded module according to claim 16, wherein the first and second bases are peelable carriers, and the method further comprises a step of peeling off the peelable carriers subsequent to the step (VII).
